(19) United States
(12) Patent Application Publication
(10) Pub. No.: US 2026/0101607 A1
(43) Pub. Date: Apr. 9, 2026

(54) OPTOELECTRONIC SEMICONDUCTOR DEVICE

(71) Applicant: EPISTAR CORPORATION, Hsinchu (TW)

(72) Inventors: Tsai CHANG DA, Hsinchu (TW); Wei-Chih PENG, Hsinchu (TW); Chu-Jih SU, Hsinchu (TW); Wei-Long CHEN, Hsinchu (TW); Chen OU, Hsinchu (TW)

(21) Appl. No.: 19/353,232

(22) Filed: Oct. 8, 2025

(30) Foreign Application Priority Data
Oct. 9, 2024 (TW) 113138423

(51) Int. Cl. H10F 77/40; H01L 25/16; H10F 39/90; H10F 77/20; H10F 77/30; H10H 29/20

(52) U.S. Cl. CPC H10F 77/413; H10F 39/90; H10F 77/206; H10F 77/306; H10H 29/20; H10W 90/00

(57) ABSTRACT

An optoelectronic semiconductor device includes a base, a semiconductor stack and a light-absorbing layer. The semiconductor stack includes a first semiconductor layer on the base, a second semiconductor layer on the first semiconductor layer, and a light absorbing layer between the first semiconductor layer and the second semiconductor layer. The first semiconductor layer includes a modified region and an unmodified region surrounding the modified region. The bonding structure is between the first semiconductor layer and the base. The first electrode structure is disposed on and connected to the second semiconductor layer. A thickness of the second semiconductor layer is less than or equal to 50 nm.

### CROSS REFERENCE TO RELATED APPLICATIONS

This Application claims the benefit of priority to Taiwanese Patent Application Serial No. 113138423, filed on Oct. 9, 2024, the contents of which is incorporated by reference herein in its entirety.

### FIELD OF DISCLOSURE

The present disclosure relates to optoelectronic semiconductor devices, and more particularly to light-absorbing optoelectronic semiconductor devices.

### BACKGROUND OF THE DISCLOSURE

The applications of semiconductor devices are extensive, and the development and research of related materials are continuously in progress. For example, group III-V semiconductor materials including group III and group V elements can be applied to various optoelectronic semiconductor devices, such as light-emitting chips (e.g., light-emitting diodes or laser diodes), light-absorbing chips (e.g., photodetectors or solar cells), or non-light-emitting chips (e.g., power devices for switching or rectification). Such devices can be utilized in fields including illumination, medical technology, display, communication, sensing, and power systems. With the advancement of technology, there remains a demand for research and development of optoelectronic semiconductor devices. Although existing optoelectronic semiconductor devices generally meet various requirements, they are not satisfactory in all aspects, and further improvements are still needed.

### SUMMARY OF THE DISCLOSURE

An optoelectronic semiconductor device includes a base, a semiconductor stack and a light-absorbing layer. The semiconductor stack includes a first semiconductor layer on the base, a second semiconductor layer on the first semiconductor layer, and a light absorbing layer between the first semiconductor layer and the second semiconductor layer. The first semiconductor layer includes a modified region and an unmodified region surrounding the modified region. The bonding structure is between the first semiconductor layer and the base.

The first electrode structure is disposed on and connected to the second semiconductor layer.

A thickness of the second semiconductor layer is less than or equal to 50 nm.

### BRIEF DESCRIPTION OF THE DRAWINGS

The embodiments of the present invention can be best understood from the following detailed description in conjunction with the accompanying drawings. It should be noted that, in accordance with standard practice in the industry, various features are not drawn to scale and are illustrated for purposes of explanation. In fact, the dimensions of various elements may be arbitrarily enlarged or reduced to clearly illustrate the features of the embodiments of the present invention.

FIG. 1 is a schematic cross-sectional view of an optoelectronic semiconductor device according to some embodiments of the present disclosure, taken along line A-A of FIG. 3.

FIG. 2A is a schematic cross-sectional view of an optoelectronic semiconductor device according to some embodiments, taken along line B-B of FIG. 3.

FIGS. 2B to 2D are schematic cross-sectional views of an optoelectronic semiconductor device according to some embodiments.

FIG. 3 is a schematic top view of an optoelectronic semiconductor device according to some embodiments.

FIGS. 4 to 13 are schematic cross-sectional views illustrating intermediate stages of forming an optoelectronic semiconductor device according to some embodiments.

FIG. 14 is a schematic cross-sectional view of an optoelectronic semiconductor device according to some embodiments, taken along line A-A of FIG. 16.

FIG. 15 is a schematic cross-sectional view of an optoelectronic semiconductor device according to some embodiments, taken along line B-B of FIG. 16.

FIG. 16 is a schematic top view of an optoelectronic semiconductor device according to some embodiments.

FIG. 17 is a schematic cross-sectional view of an optoelectronic semiconductor device according to some embodiments.

FIG. 18 is a schematic cross-sectional view of a light detection module according to some embodiments.

### DETAILED DESCRIPTION OF THE DISCLOSURE

The following disclosure provides numerous embodiments or examples for implementing various components of the subject matter provided herein. Specific examples of the components and their arrangements are described below to simplify the description of the embodiments of the present disclosure. Of course, these are merely examples and are not intended to limit the embodiments of the present disclosure. For example, when a first component is formed on a second component, the embodiment may include cases in which the first and second components are in direct contact, as well as cases in which an additional component is formed between the first and second components such that they are not in direct contact. Likewise, terminology concerning joining or connection, such as “connected” or “interconnected,” unless specifically defined otherwise, can refer to structures that are in direct physical contact or to structures that are not in direct physical contact but have other structures disposed between them. Furthermore, embodiments of the present disclosure may, in various examples, repeatedly reference numerical values and/or letters. Such repetition is for the purpose of conciseness and clarity, and is not intended to indicate any relationship between the different embodiments and/or configurations being discussed.

The compositions or materials, dopants, and defects of the various layers included in the semiconductor device of the present disclosure may be analyzed by any suitable method, such as by secondary ion mass spectrometry (SIMS), transmission electron microscopy (TEM), or scanning electron microscopy (SEM). The thickness of the various layers may also be analyzed by any suitable method, such as by transmission electron microscopy or scanning electron microscopy.

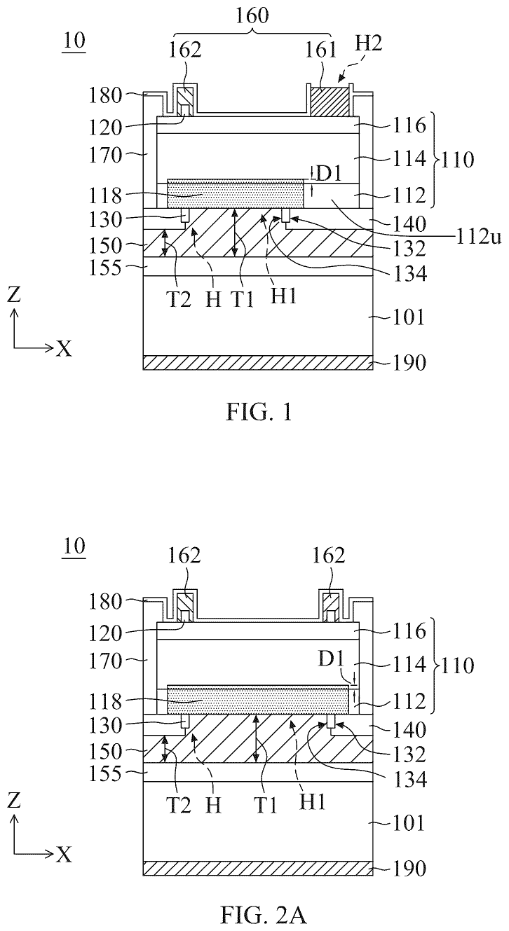

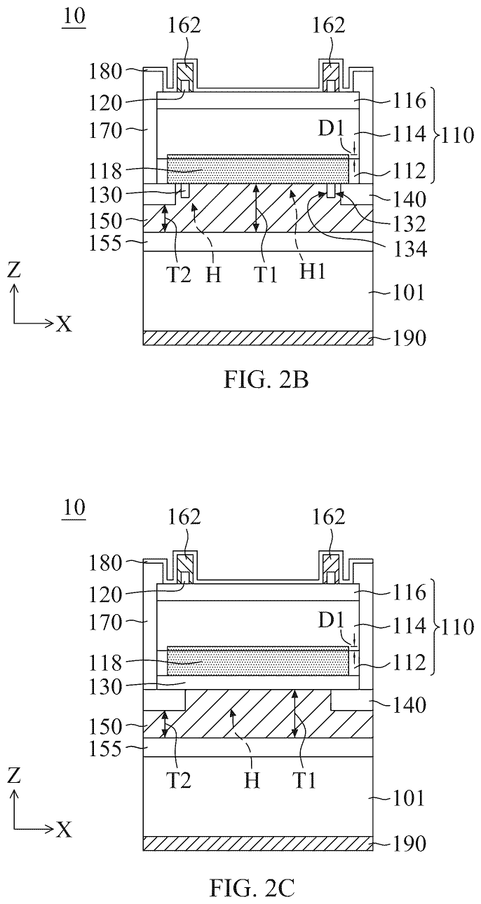

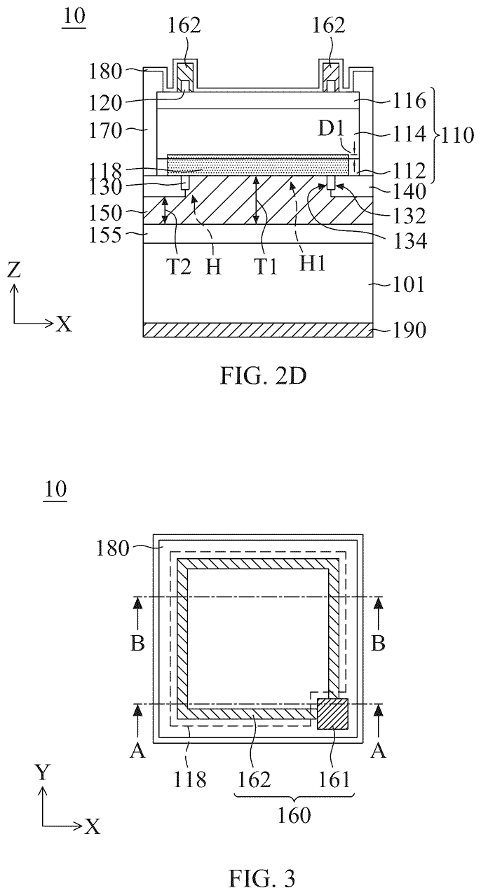

FIG. 1 and FIG. 2A are schematic cross-sectional views of an optoelectronic semiconductor device 10 according to some embodiments. FIG. 3 is a schematic top view of the optoelectronic semiconductor device 10 according to some embodiments. More specifically, FIG. 1 illustrates a schematic cross-sectional view taken along line A-A in FIG. 3, and FIG. 2A illustrates a schematic cross-sectional view taken along line B-B in FIG. 3. As shown in FIG. 1, the optoelectronic semiconductor device 10 includes a base 101, a semiconductor stack 110 disposed on the base 101, and a reflective structure 150 disposed between the base 101 and the semiconductor stack 110. In some embodiments, the optoelectronic semiconductor device 10 further includes a first electrode structure 160 and a second electrode structure 190. In some embodiments, the optoelectronic semiconductor device 10 optionally includes a first contact structure 120, a second contact structure 130, a passivation layer 140, a bonding structure 155, a protection layer 170, and/or an anti-reflective layer 180. In some embodiments, the optoelectronic semiconductor device 10 may be a photosensitive device, such as a photodiode or a photovoltaic cell.

The base 101 may be a temporary substrate or a permanent substrate supporting the semiconductor stack 110, and may be transparent or opaque. In some embodiments, the base 101 has a thickness, in a vertical direction (along the Z direction), between 100 μm and 200 μm to provide the mechanical strength required for the optoelectronic semiconductor device 10. In some embodiments, the base 101 includes a conductive material, such as gallium arsenide (GaAs), indium phosphide (InP), silicon carbide (SiC), gallium phosphide (GaP), zinc oxide (ZnO), gallium nitride (GaN), aluminum nitride (AlN), germanium (Ge), or silicon (Si).

As shown in FIG. 1 and FIG. 2A, the semiconductor stack 110 includes a first semiconductor layer 112 disposed on the base 101, a light-absorbing layer 114 disposed on the first semiconductor layer 112, a second semiconductor layer 116 disposed on the light-absorbing layer 114, and a modified region 118 formed in the first semiconductor layer 112. In detail, the modified region 118 is formed by modifying a partial region of the first semiconductor layer 112 by doping the partial region of the first semiconductor layer 112 to locally change its conductivity type. That is, the first semiconductor layer 112 includes the modified region 118 and an unmodified region 112u that has not been modified, and the unmodified region 112u surrounds the modified region 118. In some embodiments, the modified region 118 optionally extends into the light-absorbing layer 114.

In some embodiments, the first semiconductor layer 112 and the second semiconductor layer 116 have a first conductivity type, and the modified region 118 has a second conductivity type different from the first conductivity type. For example, the first semiconductor layer 112 and the second semiconductor layer 116 may be of an n-type, and the modified region 118 may be of a p-type; or the first semiconductor layer 112 and the second semiconductor layer 116 may be of a p-type, and the modified region 118 may be of an n-type. The first semiconductor layer 112 and the second semiconductor layer 116 respectively include a first dopant and a second dopant, and the first dopant and the second dopant may be the same or different. The modified region 118 includes the first dopant and a third dopant, and the third dopant is different from both the first dopant and the second dopant, and a concentration of the third dopant is greater than a concentration of the first dopant. In some embodiments, a doping concentration of the first dopant and/or the second dopant may be between 1×10¹⁷/cm³ and 5×10¹⁸/cm³. A doping concentration of the third dopant may be between 2×10¹⁷/cm³ and 5×10¹⁹/cm³. The first dopant, the second dopant, and the third dopant may respectively be zinc (Zn), beryllium (Be), magnesium (Mg), carbon (C), silicon (Si), germanium (Ge), tin (Sn), sulfur(S), selenium (Se), or tellurium (Te).

The light-absorbing layer 114 is an intrinsic semiconductor layer, that is, the light-absorbing layer 114 is undoped or unintentionally doped, thereby forming a p-i-n type photodetection device in the optoelectronic semiconductor device 10. In some embodiments, when the light-absorbing layer 114 is unintentionally doped, the light-absorbing layer 114 may include the first dopant, the second dopant, and/or the third dopant, and a doping concentration of each dopant is less than 1×10¹⁶/cm³.

The first semiconductor layer 112 has a first bandgap and a first cutoff wavelength, and is capable of absorbing light having an energy greater than or equal to the first bandgap (a wavelength less than or equal to the first cutoff wavelength). The second semiconductor layer 116 has a second bandgap and a second cutoff wavelength, and is capable of absorbing light having an energy greater than or equal to the second bandgap (a wavelength less than or equal to the second cutoff wavelength). The light-absorbing layer 114 has a third bandgap and a third cutoff wavelength, and is capable of absorbing light having an energy greater than or equal to the third bandgap (a wavelength less than or equal to the third cutoff wavelength). In some embodiments, the third bandgap is smaller than the first bandgap and the second bandgap, that is the third cutoff wavelength is greater than the first cutoff wavelength and the second cutoff wavelength, and the light-absorbing layer 114 can thus absorb a wavelength range greater than that absorbed by the first semiconductor layer 112 and that absorbed by the second semiconductor layer 116. In some embodiments, the first bandgap may be less than or equal to the second bandgap.

The wavelengths that can be absorbed by the first semiconductor layer 112, the second semiconductor layer 116, and/or the light-absorbing layer 114 are determined by their respective materials. For example, a material having a bandgap of 3.10 eV can absorb light with a wavelength of about 400 nm or less (e.g., ultraviolet light); a material having a bandgap of 2.14 eV can absorb light with a wavelength of about 580 nm or less (e.g., green light, blue light, and ultraviolet light); or a material having a bandgap of 0.73 eV can absorb light with a wavelength of about 1700 nm or less (e.g., infrared light, red light, green light, blue light, and ultraviolet light). The materials of the first semiconductor layer 112, the second semiconductor layer 116, and the light-absorbing layer 114 may include binary, ternary, or quaternary group III-V compound semiconductors, such as AlGaInAs, AlGaInP, AlInGaN, AlAsSb, InGaAsP, InGaAsN, AlGaAsP, GaAs, InGaAs, AlGaAs, AlInAs, GaAsP, GaP, InGaP, AlInP, GaN, InP, InGaN, or AlGaN.

As shown in FIG. 1 and FIG. 2A, a second semiconductor layer 116 is disposed at a light incident side of an optoelectronic semiconductor device 10, such that light first passes through the second semiconductor layer 116 before entering an absorption layer 114. Since a second cutoff wavelength of the second semiconductor layer 116 is smaller than a third cutoff wavelength of the absorption layer 114, light having a wavelength less than or equal to the second cutoff wavelength is absorbed by the second semiconductor layer 116. Light having a wavelength between the second cutoff wavelength and the third cutoff wavelength can pass through the second semiconductor layer 116 and enter the absorption layer 114, and is absorbed by the absorption layer 114 to generate electrons and holes. The electrons and holes are collected through a first electrode structure 160 and a second electrode structure 190, and output as an electrical signal (photocurrent). In other words, the optoelectronic semiconductor device 10 is primarily responsive to light having a wavelength between the second cutoff wavelength and the third cutoff wavelength, and outputs the electrical signal accordingly.

Since a light absorption effect of a semiconductor layer is proportional to its thickness, reducing a thickness of the second semiconductor layer 116 disposed at a light incident side allows more light having a wavelength less than or equal to the second cutoff wavelength to enter the absorption layer 114, thereby enhancing a responsivity of the optoelectronic semiconductor device 10 to the light having the wavelength less than or equal to the second cutoff wavelength. For example, when the second semiconductor layer 116 is indium phosphide (InP), the second cutoff wavelength is about 920 nm, which absorbs light having a wavelength less than or equal to 920 nm (e.g., visible light in a wavelength range from 400 nm to 700 nm). It is difficult for the optoelectronic semiconductor device 10 to respond to visible light. In some embodiments, by reducing the thickness of the second semiconductor layer 116, a portion of the visible light can pass through the second semiconductor layer 116 and be absorbed by the absorption layer 114. Therefore, the optoelectronic semiconductor device 10 can further respond to visible light, so that the optoelectronic semiconductor device 10 is capable of responding to both visible light and infrared light, thereby enhancing its applicability.

As shown in FIG. 1 and FIG. 2A, in the vertical direction, a thickness of an absorption layer 114 is greater than thicknesses of a first semiconductor layer 112 and a second semiconductor layer 116. The thickness of the second semiconductor layer 116 may be less than or equal to the thickness of the first semiconductor layer 112. In some embodiments, the thickness of the second semiconductor layer 116 may be less than or equal to 50 nm to enhance a responsivity of the optoelectronic semiconductor device 10 to light having a wavelength less than or equal to a second cutoff wavelength, such as a responsivity to visible light having a wavelength between 400 nm and 700 nm. The thickness of the absorption layer 114 may range from 1000 nm to 4000 nm. The thickness of the first semiconductor layer 112 may range from 500 nm to 2000 nm. In some embodiments, when a modified region 118 extends into the absorption layer 114, a thickness difference D1 between the modified region 118 and the first semiconductor layer 112 may range from 100 nm to 300 nm.

Referring to FIG. 1 and FIG. 2A, a reflective structure 150 is disposed between the first semiconductor layer 112 and a base 101, and is configured to reflect light passing through the absorption layer 114 back to the absorption layer 114 to be absorbed, thereby improving an optoelectronic conversion efficiency of the optoelectronic semiconductor device 10. In some embodiments, the reflective structure 150 is in contact with the modified region 118. In some embodiments, in a horizontal direction (along an X direction), a width of the reflective structure 150 is greater than a width of the absorption layer 114 to enhance a reflection effect. The reflective structure 150 may be a single layer or multiple layers, and may include a metal or an alloy. The metal may include copper (Cu), aluminum (Al), tin (Sn), gold (Au), or silver (Ag). The alloy may include at least two of the metals selected from the above-mentioned metals.

Referring to FIG. 1 and FIG. 2A, a passivation layer 140 is disposed between the first semiconductor layer 112 and the reflective structure 150, and includes an opening H corresponding to the modified region 118. More specifically, in the horizontal direction (along an X direction), a width of the opening H is smaller than a width of the modified region 118, such that the passivation layer 140 covers the unmodified region 112u and a periphery of the modified region 118. By providing the passivation layer 140, the reflective structure 150 is only in direct contact with the modified region 118 through the opening H, and is not in direct contact with the unmodified region 112u for reducing a dark current. The passivation layer 140 may include an insulating material, such as tantalum oxide (TaOₓ), aluminum oxide (AlOₓ), silicon oxide (SiOₓ), titanium oxide (TiOₓ), silicon nitride (SiNₓ), silicon oxynitride (SiOₓN_{y}), niobium pentoxide (Nb₂O₅), magnesium fluoride (MgFₓ), or zirconium oxide (ZrO₂).

As shown in FIG. 1 and FIG. 2A, a reflective structure 150 has a first thickness T1 in a portion not overlapping the passivation layer 140, and has a second thickness T2 in a portion overlapping the passivation layer 140. More specifically, the first thickness T1 is a maximum thickness of the reflective structure 150 in the vertical direction, and the second thickness T2 is a difference between the first thickness T1 and a thickness of the passivation layer 140. In some embodiments, the first thickness T1 is greater than the second thickness T2. In some embodiments, the thickness of the passivation layer 140 is smaller than the second thickness T2 of the reflective structure 150. In some embodiments, the first thickness T1 of the reflective structure 150 may range from 500 nm to 1500 nm. The thickness of the passivation layer 140 may range from 100 nm to 500 nm.

Referring to FIG. 1, FIG. 2A, and FIG. 3, a first electrode structure 160 is disposed above the second semiconductor layer 116 and is electrically connected to the second semiconductor layer 116. A second electrode structure 190 is located below a base 101, and is electrically connected to the modified region 118 through the base 101 and the reflective structure 150, such that the optoelectronic semiconductor device 10 forms a vertical structure. In some embodiments, the first electrode structure 160 includes an electrode pad 161 and an extension portion 162 connected to the electrode pad 161. As shown in FIG. 3, the extension portion 162 is annular and may be disposed along an edge of the modified region 118. In some embodiments, in the vertical direction, the extension portion 162 may fully overlap, partially overlap, or not overlap with the modified region 118. In some embodiments, in a top view, the electrode pad 161 may optionally be disposed outside the modified region 118, that is, the electrode pad 161 may not overlap with the modified region 118 in the vertical direction, to reduce a light shielding effect.

Referring to FIG. 1 and FIG. 2A, a first contact structure 120 is disposed between the first electrode structure 160 and the second semiconductor layer 116 to reduce a contact resistance of the first electrode structure 160. Specifically, the first contact structure 120 is disposed between the extension portion 162 and the second semiconductor layer 116, and may optionally be disposed between the electrode pad 161 and the second semiconductor layer 116. The first contact structure 120 is covered by the first electrode structure 160, and may vertically overlap with the modified region 118. The first contact structure 120 may be patterned. In some embodiments, the first contact structure 120 may be disposed corresponding to the extension portion 162. For example, the first contact structure 120 is disposed along an edge of the modified region 118 and is formed in an annular shape. The first contact structure 120 and the extension portion 162 may have the same shape. In some embodiments, the first contact structure 120 may not vertically overlap with the unmodified region 112u. In some embodiments, in the horizontal direction, a width of the first contact structure 120 may be equal to or smaller than a width of the extension portion 162. In some embodiments, a thickness of the first contact structure 120 may range from 50 nm to 150 nm.

Referring to FIG. 1 and FIG. 2A, a second contact structure 130 is disposed between the first semiconductor layer 112 and the reflective structure 150 to reduce a contact resistance therebetween. In some embodiments, the second contact structure 130 contacts the modified region 118 and does not contact the unmodified region 112u. In the present embodiment, the second contact structure 130 is located within the opening H, and the second contact structure 130 may be patterned. For example, the second contact structure 130 is disposed along an edge of the modified region 118 and is formed in an annular shape with an opening H1. The reflective structure 150 fills the opening H1 to contact the modified region 118. Specifically, the second contact structure 130 includes a first side surface 132 and a second side surface 134. The first side surface 132 is connected to the passivation layer 140, and the second side surface 134 is connected to the reflective structure 150. In some embodiments, the second contact structure 130 and the first contact structure 120 may correspond to and vertically overlap each other. In some embodiments, the second contact structure 130 may have a thickness between 50 nm and 150 nm.

The first contact structure 120 and/or the second contact structure 130 may include a binary, ternary, or quaternary group III-V compound semiconductor, such as AlGaInAs, AlGaInP, AlInGaN, AlAsSb, InGaAsP, InGaAsN, AlGaAsP, GaAs, InGaAs, AlGaAs, AlInAs, GaAsP, GaP, InGaP, AlInP, GaN, InP, InGaN, or AlGaN. In some embodiments, the first contact structure 120 may have a fourth dopant and have the same conductivity type as the second semiconductor layer 116, and a doping concentration of the fourth dopant in the first contact structure 120 is greater than a doping concentration of a second dopant in the second semiconductor layer 116. The fourth dopant and the second dopant may be the same or different. In some embodiments, the second contact structure 130 may have a fifth dopant and have the same conductivity type as the modified region 118, and a doping concentration of the fifth dopant in the second contact structure 130 is greater than a doping concentration of a third dopant in the modified region 118. The fifth dopant and the third dopant may be the same or different.

Referring to FIG. 1 and FIG. 2A, a bonding structure 155 is disposed between the base 101 and the reflective structure 150 to bond the base 101 to the reflective structure 150. The bonding structure 155 may include a metal, an alloy, or a metal oxide. The metal may include aluminum (Al), nickel (Ni), gold (Au), silver (Ag), titanium (Ti), tungsten (W), platinum (Pt), tin (Sn), indium (In), copper (Cu), or the like. The alloy may include at least two of the metals selected from the group consisting of the above-mentioned metals. The metal oxide may include indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), zinc oxide (ZnO), gallium phosphide (GaP), indium cerium oxide (ICO), indium tungsten oxide (IWO), indium titanium oxide (ITiO), indium zinc oxide (IZO), indium gallium oxide (IGO), gallium aluminum zinc oxide (GAZO), or a combination thereof.

Referring to FIG. 1 and FIG. 2A, a protection layer 170 is disposed above the base 101 and covers a sidewall of a semiconductor stack 110, and may optionally cover a portion of a top surface of the semiconductor stack 110 to improve a reliability of the optoelectronic semiconductor device 10. When the optoelectronic semiconductor device 10 is a photodiode, the protection layer 170 may reduce a dark current of the photodiode. In some embodiments, the protection layer 170 extends under the electrode pad 161 (not shown). The protection layer 170 may include an insulating material, such as tantalum oxide (TaOₓ), aluminum oxide (AlOₓ), silicon oxide (SiOₓ), titanium oxide (TiOₓ), silicon nitride (SiNₓ), silicon oxynitride (SiOₓN_{y}), niobium pentoxide (Nb₂O₅), zirconium oxide (ZrO₂), or spin-on glass (SOG).

Referring to FIG. 1 and FIG. 2A, an anti-reflection layer 180 is disposed on a surface of the second semiconductor layer 116 to improve an optoelectronic conversion efficiency of the optoelectronic semiconductor device 10. In some embodiments, the anti-reflection layer 180 covers or conformally covers the protection layer 170 and the first electrode structure 160. The anti-reflection layer 180 has an opening H2 corresponding to a position of the electrode pad 161, to allow an external power source (not shown) to connect to the electrode pad 161. The anti-reflection layer 180 may include an insulating material, such as aluminum oxide (AlOₓ), silicon oxide (SiOₓ), titanium oxide (TiOₓ), silicon nitride (SiNₓ), silicon oxynitride (SiOₓN_{y}), or niobium pentoxide (Nb₂O₅).

Some embodiments of the optoelectronic semiconductor device 10 of the present disclosure may be referred to FIG. 2B, FIG. 2C, and FIG. 2D.

As shown in FIG. 2B, both a first side surface 132 and a second side surface 134 of the second contact structure 130 are covered by the reflective structure 150, that is, the second contact structure 130 is not in direct contact with the passivation layer 140.

As shown in FIG. 2C, the second contact structure 130 is not patterned and does not have the opening H1, and the reflective structure 150 contacts the second contact structure 130 and does not contact the modified region 118.

As shown in FIG. 2D, a thickness of the first semiconductor layer 112 is substantially the same as a thickness of the second semiconductor layer 116 (less than or equal to 50 nm), thereby reducing absorption of light passing through the absorption layer 114 and/or light reflected by the reflective structure 150 by the first semiconductor layer 112, and further improving a responsivity of the optoelectronic semiconductor device 10.

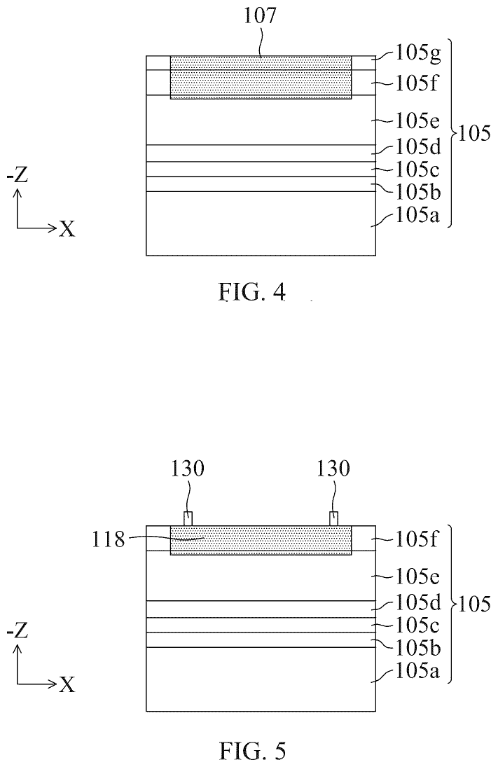

The method for manufacturing the optoelectronic semiconductor device 10 will now be described with reference to FIGS. 4 to 13. First, referring to t FIG. 4, in this step, an epitaxial structure 105 is provided, and the epitaxial structure 105 is subjected to a diffusion process to form a diffusion region 107 therein. The epitaxial structure 105 may include semiconductor layers 105a to 105g sequentially stacked along the vertical direction (−Z direction). In some embodiments, the semiconductor layer 105a and the semiconductor layer 105b may respectively serve as a growth substrate and a buffer layer for forming the epitaxial structure 105; the semiconductor layer 105c may serve as the first contact structure 120; the semiconductor layer 105d may serve as the second semiconductor layer 116; the semiconductor layer 105e may serve as the absorption layer 114; the semiconductor layer 105f may serve as the first semiconductor layer 112; and the semiconductor layer 105g may serve as the second contact structure 130 (which will be described in detail below). In some embodiments, each of the semiconductor layers in the epitaxial structure 105 may be doped with different elements during an epitaxial process to obtain a specific conductivity type. For example, the semiconductor layer 105c, the semiconductor layer 105d, and/or the semiconductor layer 105f may be doped to have a first conductivity type. The diffusion region 107 is formed in the semiconductor layer 105g and the semiconductor layer 105f, and may optionally extend into the semiconductor layer 105e. In some embodiments, the diffusion region 107 may have a second conductivity type different from the first conductivity type.

The epitaxial structure 105 may be formed by an epitaxial growth process such as molecular beam epitaxy (MBE), metal-organic chemical vapor deposition (MOCVD), or hydride vapor phase epitaxy (HVPE).

Next, referring to FIG. 5, in this step, the semiconductor layer 105g is subjected to a patterning process to form the second contact structure 130 and to expose an upper surface of the semiconductor layer 105f, while remaining portions of the diffusion region 107 located in the semiconductor layer 105e and the semiconductor layer 105f form the modified region 118. The second contact structure 130 may be a portion of the semiconductor layer 105g located within the diffusion region 107 and may have the same conductivity type as the diffusion region 107.

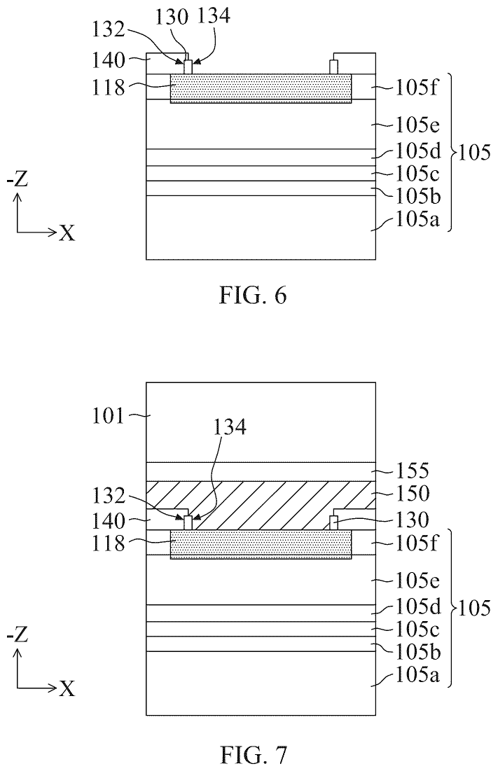

Next, referring to FIG. 6, in this step, a patterned passivation layer 140 is formed to cover the semiconductor layer 105f and/or the second contact structure 130, and to expose the modified region 118. More specifically, the passivation layer 140 may optionally cover a portion of the second contact structure 130, and may cover a first side surface 132 of the second contact structure 130 while exposing a second side surface 134 of the second contact structure 130.

Next, referring to FIG. 7, in this step, a reflective structure 150 is formed to cover the passivation layer 140, the modified region 118, and the second contact structure 130, and a bonding structure 155 is formed on the reflective structure 150 to bond the base 101 to the reflective structure 150.

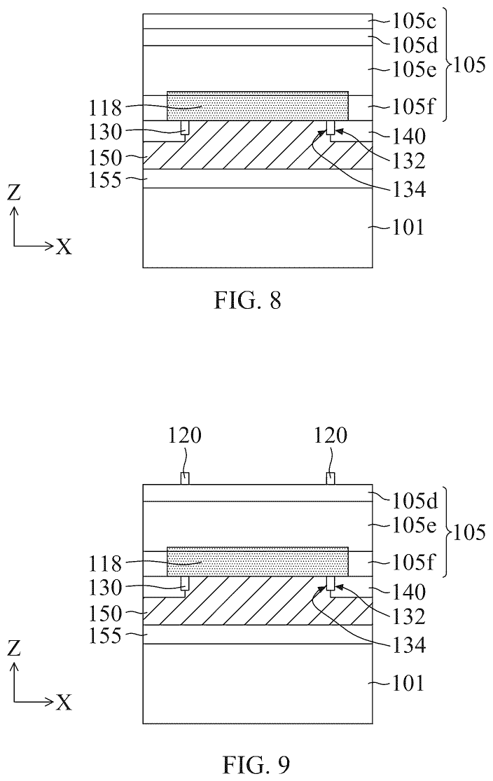

The structure of FIG. 7 may optionally be flipped upside down for subsequent processes. For convenience of description, FIGS. 8 to 11 illustrate the structure of FIG. 7 after being flipped.

Next, referring to FIG. 8, in this step, the semiconductor layer 105a serving as a growth substrate and the semiconductor layer 105b serving as a buffer layer are removed to expose the semiconductor layer 105c.

Next, referring to FIG. 9, in this step, the semiconductor layer 105c is subjected to a patterning process to form the first contact structure 120 and to expose the semiconductor layer 105d.

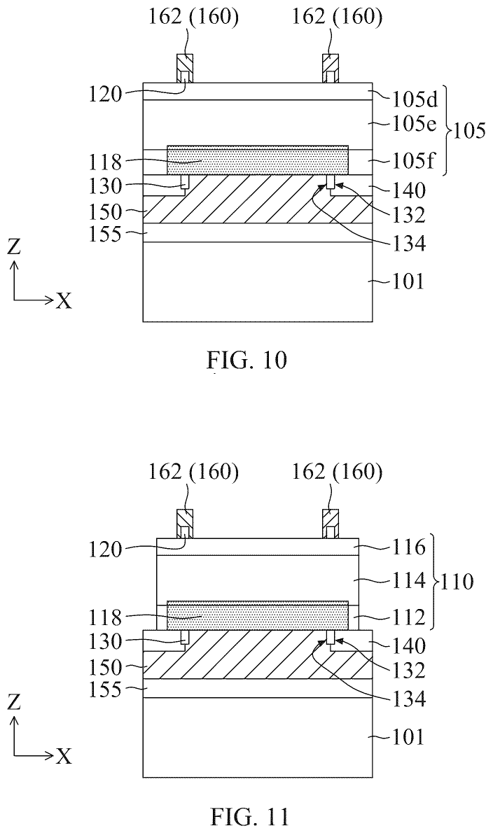

Subsequently, referring to FIG. 10, in this step, a first electrode structure 160 is formed on the first contact structure 120 and the semiconductor layer 105d, and the first electrode structure 160 may optionally cover a sidewall of the first contact structure 120. Referring to FIG. 1, the first electrode structure 160 includes an electrode pad 161 and an extension portion 162; however, in FIG. 10, only the extension portion 162 is illustrated.

Next, referring to FIG. 11, in this step, the epitaxial structure 105 is subjected to a mesa process to form the semiconductor stack 110. More specifically, after the mesa process, the semiconductor layer 105f is formed as the first semiconductor layer 112, the semiconductor layer 105e is formed as the absorption layer 114, and the semiconductor layer 105d is formed as the second semiconductor layer 116. The first semiconductor layer 112, the absorption layer 114, and the second semiconductor layer 116 together form the semiconductor stack 110. The modified region 118 is formed in the first semiconductor layer 112 and extends into the absorption layer 114. In some embodiments, the mesa process may be omitted according to actual requirements, such that the semiconductor layer 105f, the semiconductor layer 105e, and the semiconductor layer 105d are the first semiconductor layer 112, the absorption layer 114, and the second semiconductor layer 116, respectively (not shown).

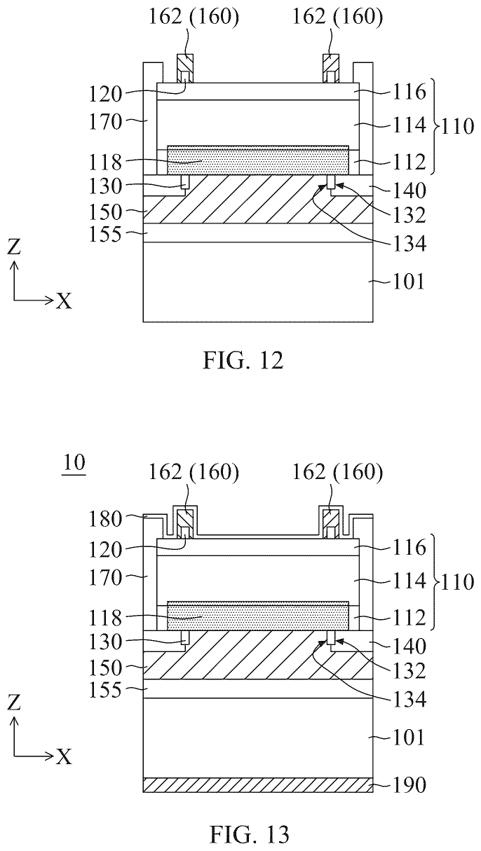

Next, referring to FIG. 12, in this step, a patterned protection layer 170 is formed to cover a sidewall of the semiconductor stack 110 and a portion of the semiconductor stack 110, to expose a portion of a top surface of the second semiconductor layer 116 and the first electrode structure 160.

Then, referring to FIG. 13, in this step, an anti-reflection layer 180 is formed over the protection layer 170 and the first electrode structure 160, and a second electrode structure 190 is formed under the base 101, so as to form the optoelectronic semiconductor device 10 as shown in FIGS. 1, 2A, and 3. The anti-reflection layer 180 may cover or conformally cover the protection layer 170, the second semiconductor layer 116, and the first electrode structure 160. The second electrode structure 190 is in direct contact with the base 101 and is electrically connected to the modified region 118 through the bonding structure 155 and the reflective structure 150.

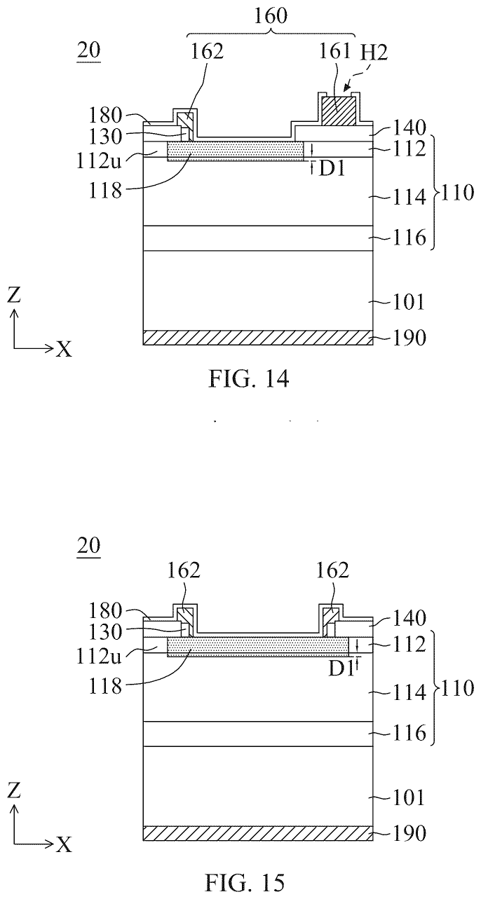

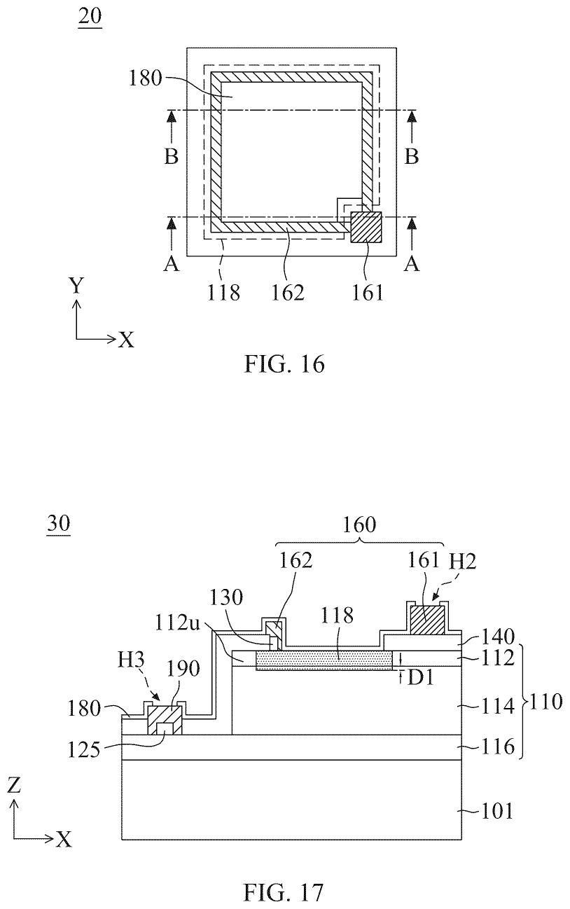

FIGS. 14 and 15 are schematic cross-sectional views of an optoelectronic semiconductor device 20 according to some embodiments of the present disclosure. FIG. 16 is a schematic top view of the optoelectronic semiconductor device 20. More specifically, FIG. 14 and FIG. 15 respectively illustrate schematic cross-sectional views taken along line A-A and line B-B in FIG. 16. The structure of the optoelectronic semiconductor device 20 is similar to that of the optoelectronic semiconductor device 10 shown in FIGS. 1, 2A, and 3, except that the optoelectronic semiconductor device 20 does not include the reflective structure 150, the bonding structure 155, the first contact structure 120, and the protection layer 170. In some embodiments, the second semiconductor layer 116 is closer to the base 101 and the first semiconductor layer 112 is farther from the base 101, that is, the first semiconductor layer 112 is located at a light incident side of the optoelectronic semiconductor device 20. The modified region 118 is formed in the first semiconductor layer 112 and may optionally extend into the light-absorbing layer 114. The dopants and conductivity types of the first semiconductor layer 112, the second semiconductor layer 116, and the modified region 118 may be referred to the foregoing description of the optoelectronic semiconductor device 10. In some embodiments, the thickness of the first semiconductor layer 112 may be less than or equal to 50 nm to increase the responsivity of the optoelectronic semiconductor device 20 to visible light. The thickness of the second semiconductor layer 116 may be between 500 nm and 2000 nm.

As shown in FIGS. 14 and 15, the first electrode structure 160 is disposed on the first semiconductor layer 112, and the second contact structure 130 is located between the first semiconductor layer 112 and the first electrode structure 160. More specifically, in some embodiments, an electrode pad 162 is disposed on the passivation layer 140 without directly contacting the second semiconductor layer 116, and an extension portion 162 is connected to the modified region 118 and/or the passivation layer 140. The second contact structure 130 is disposed between the extension portion 162 and the modified region 118, thereby electrically connecting the first electrode structure 160 to the modified region 118. The second electrode structure 190 is electrically connected to the second semiconductor layer 116 through the base 101, so that the optoelectronic semiconductor device 20 forms a vertical structure. An anti-reflective layer 180 is disposed on the first semiconductor layer 112 and conformally covers the passivation layer 140, the first electrode structure 160, and the modified region 118. The positions, compositions, and properties of other layers or structures of the optoelectronic semiconductor device 20 may be referred to the foregoing description of the previous embodiments, and thus are not repeated herein.

FIG. 17 is a schematic cross-sectional view of an optoelectronic semiconductor device 30 according to some embodiments of the present disclosure. The structure of the optoelectronic semiconductor device 30 is similar to that of the optoelectronic semiconductor device 20 shown in FIGS. 14 and 15, except that the widths of the second semiconductor layer 116 and the base 101 are greater than the width of the light-absorbing layer 114, so that the second semiconductor layer 116 has an exposed region not covered by the light-absorbing layer 114 and the first semiconductor layer 112. In some embodiments, the second electrode structure 190 is disposed on the exposed region of the second semiconductor layer 116, and the second electrode structure 190 and the first electrode structure 160 are located at the same side of the base 101, such that the optoelectronic semiconductor device 30 forms a lateral structure. In some embodiments, the base 101 may include the aforementioned conductive material or an insulating material, such as sapphire, glass, or quartz.

The passivation layer 140 and/or the anti-reflective layer 180 may extend to cover sidewalls of the light-absorbing layer 114 and the first semiconductor layer 112, as well as an exposed region of the second semiconductor layer 116. In some embodiments, the optoelectronic semiconductor device 30 optionally includes a third contact structure 125 disposed between the second electrode structure 190 and the second semiconductor layer 116 to reduce contact resistance therebetween. In some embodiments, the anti-reflective layer 180 may further include an opening H3, the position of which corresponds to the position of the second electrode structure 190, to allow an external power source (not shown) to be connected to the second electrode structure 190. The positions, compositions, and properties of other layers or structures of the optoelectronic semiconductor device 30 may be referred to the foregoing descriptions of the previous embodiments, and thus are not repeated herein.

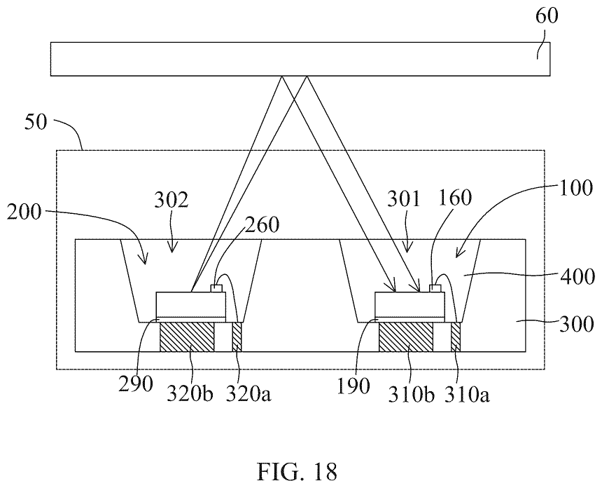

FIG. 18 illustrates a light detection module 50 and its application according to some embodiments of the present disclosure. The light detection module 50 includes a carrier board 300, a light-emitting device 200, a photosensitive device 100, and a packaging structure 400. The carrier board 300 has a first recess 301 and a second recess 302, in which the photosensitive device 100 and the light-emitting device 200 are respectively disposed. The packaging structure 400 covers the photosensitive device 100 and the light-emitting device 200 located in the first recess 301 and the second recess 302. The photosensitive device 100 may be any of the optoelectronic semiconductor devices 10, 20, or 30 described in the foregoing embodiments. The light-emitting device 200 includes a third electrode structure 260 and a fourth electrode structure 290, and includes an active layer capable of emitting light of a specific wavelength, such as, visible light having a wavelength between 400 nm and 700 nm, or infrared light having a wavelength between 800 nm and 2000 nm, such as 520 nm, 660 nm, 850 nm, 940 nm, 1050 nm, 1070 nm, 1100 nm, 1300 nm, 1500 nm, or 1700 nm. The wavelength of the light emitted by the light-emitting device 200 is within a responsive wavelength range of the photosensitive device 100. The light-emitting device 200 and the photosensitive device 100 may include the same material, for example, the active layer of the light-emitting device 200 and the light-absorbing layer of the photosensitive device 100 may both include materials such as AlInGaAs, AlGaInP, InGaAs, or InGaAsP.

The carrier board 300 includes a first circuit structure 310a and 310b corresponding to and electrically connected to the first electrode structure 160 and the second electrode structure 190 of the photosensitive device 100, and a second circuit structure 320a and 320b corresponding to and electrically connected to the third electrode structure 260 and the fourth electrode structure 290 of the light-emitting device 200, so as to supply power required for the light-emitting device 200 to emit light and to receive an electrical signal (e.g., a current or a voltage) generated by the photosensitive device 100. The carrier board 300 may be, such as, a package submount or a printed circuit board (PCB). The first electrode structure 160, the second electrode structure 190, the third electrode structure 260, the fourth electrode structure 290, the first circuit structure 310a and 310b, and the second circuit structure 320a and 320b may be single-layer or multi-layer structures, and include at least one material selected from the group consisting of nickel (Ni), titanium (Ti), platinum (Pt), palladium (Pd), silver (Ag), gold (Au), aluminum (Al), and copper (Cu). The packaging structure 400 includes an organic polymer material or an inorganic dielectric material, such as epoxy or silicone.

The light detection module 50 may be applied to a mobile device or a wearable device, such as, as a proximity sensor, a structured light scanner, or a biosensor. When a device including the light detection module 50 of the present disclosure is brought close to an object 60 to be measured, light of a specific wavelength emitted from the light-emitting device 200 is projected onto the object 60 and reflected to the photosensitive device 100, causing the photosensitive device 100 to generate a response and output an electrical signal. In some embodiments, the light detection module 50 may further include another light-emitting device (not shown) for emitting light of a specific wavelength to be projected onto the object 60 and reflected to the photosensitive device 100, causing the photosensitive device 100 to generate a response and output an electrical signal. The wavelength of the light emitted from the another light-emitting device is within a responsive wavelength range of the photosensitive device 100, and is different from the wavelength of the light emitted from the light-emitting device 200. For example, the light-emitting device 200 and the another light-emitting device may respectively emit infrared light and visible light, and the photosensitive device 100 is responsive to both the infrared light and the visible light. Accordingly, the light detection module 50 can detect multiple types of signals and thus has a broader range of applications, for example, the light detection module 50 is a biosensor capable of simultaneously detecting two or more different biometric characteristics. The biometric characteristics may include, heart rate, blood oxygen level, blood glucose level, or blood pressure.

In summary, in some embodiments of the present disclosure, by appropriately thinning the thickness of the semiconductor layer located on the light incident side, the absorption range of the optoelectronic semiconductor device can be further expanded to increase its applicability. In some embodiments of the present disclosure, a reflective structure is further incorporated to enhance the light absorption efficiency, thereby improving the performance of the optoelectronic semiconductor device.

The semiconductor device of the present disclosure may be applied to products in the fields of communications and sensing, such as mobile phones, tablet computers, automotive driver-assistance devices, televisions, computers, rangefinders, biosensing devices, gas sensors, and wearable devices (e.g., watches, wristbands, earphones, etc.).

While the present invention has been disclosed above by way of the embodiments, various modifications and changes may be made without departing from the spirit and scope of the present invention, and the scope of protection of the present invention shall be defined by the appended claims. The contents of the above embodiments may be combined or substituted with each other as appropriate, and are not limited to the specific embodiments described herein. For example, specific parameters of components or the connection relationships between specific components and other components disclosed in one embodiment may also be applied to other embodiments, all of which fall within the scope of protection of the present invention.

What is claimed is:

1. An optoelectronic semiconductor device, comprising:
a base;
a semiconductor stack, comprising
a first semiconductor layer disposed on the base;
a second semiconductor layer disposed on the first semiconductor layer and has a thickness less than or equal to 50 nm. ; and
a light-absorbing layer disposed between the first semiconductor layer and the second semiconductor layer;
wherein the first semiconductor layer comprises a modified region and an unmodified region surrounding the modified region; and
a bonding structure disposed between the first semiconductor layer and the base; and
a first electrode structure disposed on and connected to the second semiconductor layer.

2. The optoelectronic semiconductor device according to claim 1, wherein the first semiconductor layer has a thickness greater than that of the second semiconductor layer.

3. The optoelectronic semiconductor device according to claim 1, further comprising a first contact structure disposed between the second semiconductor layer and the first electrode structure.

4. The optoelectronic semiconductor device according to claim 3, wherein the first contact structure overlaps with the modified region in a vertical direction.

5. The optoelectronic semiconductor device according to claim 1, further comprising a protection layer covering a sidewall of the semiconductor stack.

6. The optoelectronic semiconductor device according to claim 1, further comprising a reflective structure disposed between the first semiconductor layer and the bonding structure, and the reflective structure is in contact with the first semiconductor layer.

7. The optoelectronic semiconductor device according to claim 6, wherein the reflective structure is in direct contact with the modified region, and is not in direct contact with the unmodified region.

8. The optoelectronic semiconductor device according to claim 6, wherein the reflective structure comprises a first portion connecting the modified region and a second portion separated from the modified region.

9. The optoelectronic semiconductor device according to claim 8, wherein the first portion has a
first thickness, and the second portion has a second thickness less than the first thickness

10. The optoelectronic semiconductor device according to claim 6, wherein, in a horizontal direction, the reflective structure has a width greater than that of the light-absorbing layer.

11. The optoelectronic semiconductor device according to claim 6, further comprising a passivation layer disposed between the first semiconductor layer and the reflective structure, wherein the passivation layer comprises a first opening corresponding to the modified region.

12. The optoelectronic semiconductor device according to claim 11, wherein, in a horizontal direction, the first opening has a width less than that of the modified region.

13. The optoelectronic semiconductor device according to claim 11, wherein the passivation layer is in contact with the unmodified region and the modified region.

14. The optoelectronic semiconductor device according to claim 11, further comprising a second contact structure disposed between the first semiconductor layer and the reflective structure, wherein the second contact structure contacts the modified region and does not contact the unmodified region.

15. The optoelectronic semiconductor device according to claim 14, wherein the second contact structure is located within the first opening.

16. The optoelectronic semiconductor device according to claim 14, wherein the second contact structure comprises a side surface connected to the passivation layer.

17. The optoelectronic semiconductor device according to claim 14, wherein the second contact structure comprises a second opening corresponding to the modified region, and the second opening has a width less than that of the first opening.

18. The optoelectronic semiconductor device according to claim 1, further comprising an anti-reflective layer disposed on a surface of the second semiconductor layer.

19. A light detection module, comprising:
a carrier board;
a light-emitting device located on the carrier board and emitting a light; and
the optoelectronic semiconductor device of claim 1 located on the carrier board and detecting the light

20. The light detection module of claim 19, further comprising a packaging structure covering the light-emitting device and the optoelectronic semiconductor device.
